(19) United States
(12) Patent Application Publication
(10) Pub. No.: US 2009/0122822 A1
(43) Pub. Date: May 14, 2009

(54) Semiconductor device having trench extending perpendicularly to cleaved plane and manufacturing method of the same

(75) Inventor: Masahiro Murayama, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-fu (JP)

(21) Appl. No.: 12/232,264

(22) Filed: Sep. 12, 2008

(30) Foreign Application Priority Data
Sep. 14, 2007 (JP) 2007-239642

(51) Int. Cl. H01S 5/323; H01L 21/304; H01L 29/15

(52) U.S. Cl. 372/43.01; 438/462; 257/14; 257/E21.238; 257/E29.072

(57) ABSTRACT

A method for manufacturing a semiconductor device includes setting cut lines in parallel to a normal direction of a (1-100) plane orthogonal to the principal plane and in parallel to a normal direction of a (11-20) plane orthogonal to the (1-100) plane; forming, along the cut line parallel to the normal direction of the (1-100) plane, a trench from the principal plane of the semiconductor layer to a midpoint of a boundary plane between the semiconductor layer and the substrate; and cutting the wafer along the cut lines to divide the wafer into the plurality of semiconductor device where four side faces which are nonpolar planes orthogonal to the principal plane are set adjacent to the principal plane.

### CROSS REFERENCE TO RELATED APPLICATIONS AND INCORPORATION BY REFERENCE

This application is based upon and claims the benefit of priority from prior Japanese Patent Application P2007-239642 filed on Sep. 14, 2007; the entire contents of which are incorporated by reference herein.

### BACKGROUND OF THE INVENTION

1. Field of the Invention

The present invention relates to a semiconductor device including a substrate of a hexagonal structure, and manufacturing method of the same.

2. Description of the Related Art

Generally, to divide a substrate having a semiconductor film formed therein to manufacture a chip, division by dicing or cleaving by a scriber is used. In the case of division by dicing, for example, the substrate is cut from its back or front by a blade rotated fast at one or multiple stages to be divided. In the case of cleaving by a scriber, a trench is formed in the substrate by a pen or the like having a diamond disposed in its tip, and the substrate is cleaved along the trench to be divided. Ordinarily, in a semiconductor device which uses a nitride-base compound semiconductor, the nitride-base compound semiconductor is hard, and thus a substrate surface is marked off with a desired chip shape to manufacture a chip.

In the case of forming a semiconductor device manufactured by using a substrate having a hexagonal crystal structure such as a gallium nitride (GaN) substrate into a chip, a crystal plane of the substrate has to be taken into consideration. It is because in the hexagonal structure where a—c-plane (polar plane) is a principal plane, a plane cleaved most easily (“cleaved plane” hereinafter) is a [1-100] plane called an m-plane (nonpolar plane). This m-plane corresponds to a-side face of a hexagonal column parallel to a c-axis (0001).

Thus, when the substrate surface is marked off along a plane other than the substrate of the hexagonal structure and the cleaved plane of the semiconductor film crystal-grown on the substrate, cracks easily occur along the cleaved plane. Consequently, when the semiconductor device is manufactured into a chip of a desired shape, a yield of the semiconductor device may be reduced. Especially, in a semiconductor device of a ridge structure, it is often the case that cracks occur in a surface of the semiconductor device from a marked-off portion to a step portion of the ridge. To solve this problem, a method for forming split slots in a front and a back of a wafer to form a split line in a direction other than a cleaved plane has been proposed.

However, the aforementioned method increases the number of steps by adding the step of forming the split slots. Besides, when the split slots are formed, cracks occur or the wafer is split to cause a reduction in yield of the semiconductor device.

### SUMMARY OF THE INVENTION

The present invention provides a semiconductor device including a substrate of a hexagonal structure where a reduction in yield caused by cracks generated due to chip manufacture is suppressed, and its manufacturing method of the same.

An aspect of the present invention is a method for manufacturing a semiconductor device, in which a wafer is divided into a plurality of semiconductor device, the wafer including a semiconductor layer made of a nitride-base compound semiconductor of a hexagonal structure and stacked on a substrate where a polar plane is a principal plane. The method for manufacturing a semiconductor device comprising: setting cut lines in parallel to a normal direction of a (1-100) plane orthogonal to the principal plane and in parallel to a normal direction of a (11-20) plane orthogonal to the (1-100) plane; forming, along the cut line parallel to the normal direction of the (1-100) plane, a trench from the principal plane of the semiconductor layer to a midpoint of the principal plane and a boundary plane which is between the semiconductor layer and the substrate; and cutting the wafer along the cut lines to divide the wafer into the plurality of semiconductor device where four side faces which are nonpolar planes orthogonal to the principal plane are set adjacent to the principal plane.

Another aspect of the present invention is a semiconductor device comprising a substrate made of a semiconductor of a hexagonal structure and including a substrate principal plane which is a polar plane; and a semiconductor layer made of a nitride-base compound semiconductor of a hexagonal structure and disposed on the substrate principal plane, and including a principal plane as a polar plane, an m-side face as a (1-100) plane orthogonal to the principal plane, and an a-side face as a (11-20) plane orthogonal to the (1-100) plane disposed adjacently to the principal plane, an outer edge portion of a section along the (1-100) plane being mesa-shaped.

Still another aspect of the present invention is a semiconductor laser in which a nitride semiconductor layer is stacked on a gallium nitride substrate. The semiconductor laser comprises a ridge stripe formed by etching the nitride semiconductor layer; and a step portion formed by etching the nitride semiconductor layer, the step portion being provided parallel to the ridge strip on a side face of the semiconductor laser, wherein the side surface is adjacent to a principal plane of the gallium nitride substrate and to a resonance plane of the semiconductor laser.

### BRIEF DESCRIPTION OF THE DRAWINGS

FIG. 1 is a top view illustrating a semiconductor device according to a first embodiment of the present invention.

FIG. 2 is a sectional view cut along the line II-II of the semiconductor device illustrated in FIG. 1.

FIG. 3 is a schematic view illustrating a crack generated in the semiconductor device of the first embodiment of the invention.

FIG. 4 is a schematic view illustrating a crack generated in a semiconductor device of a related art.

FIG. 5 is a schematic view illustrating a hexagonal crystal structure.

FIG. 6 is a schematic view illustrating an upper surface of the semiconductor device of the embodiment of the invention along with hexagonal structures and cut lines.

FIG. 7 is a process sectional view illustrating a method for manufacturing the semiconductor device of the first embodiment of the invention.

FIG. 8 is a top view illustrating a semiconductor device according to a second embodiment of the present invention.

FIG. 9 is a sectional view cut along the line IX-IX of the semiconductor device illustrated in FIG. 8.

FIG. 10 is a process top view illustrating an exemplary method for manufacturing the semiconductor device of the second embodiment of the invention.

FIG. 11 is a process sectional view illustrating another example of the method for manufacturing the semiconductor device of the first embodiment of the invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

Generally and as it is conventional in the representation of semiconductor devices, it will be appreciated that the various drawings are not drawn to scale from one figure to another nor inside a given figure.

In the following descriptions, numerous specific details are set forth such as specific signal values, etc., to provide a thorough understanding of the present invention. However, it will be obvious to those skilled in the art that the present invention may be practiced without such specific details. In other instances, well-known circuits have been shown in block diagram form in order not to obscure the present invention in unnecessary detail.

### First Embodiment

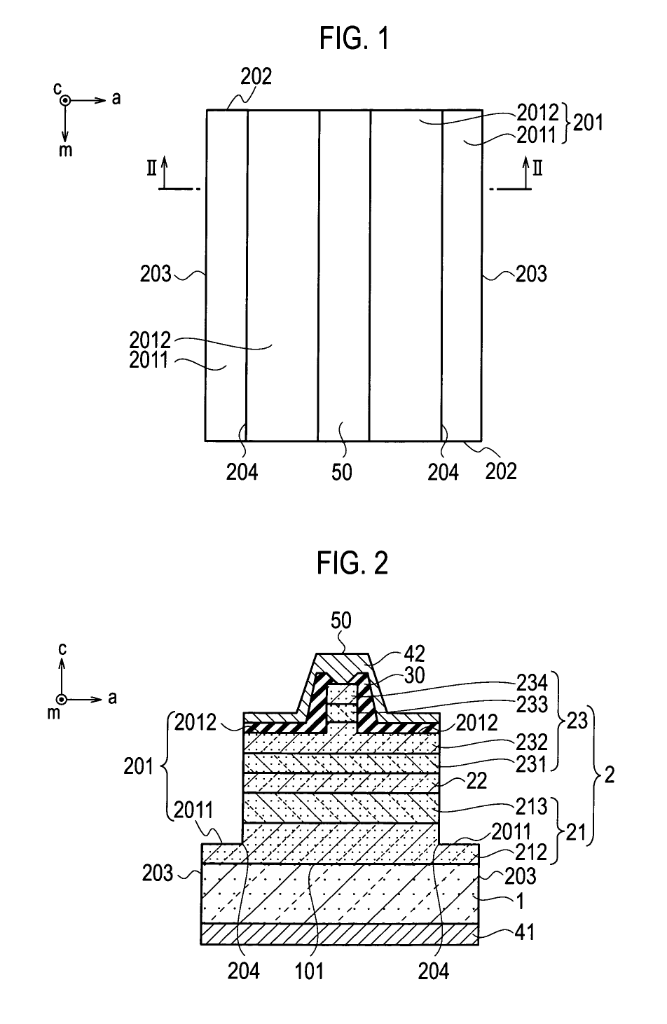

According to a first embodiment of the present invention, as illustrated in a top view of FIG. 1 and a sectional view of FIG. 2 cut along the line II-II of FIG. 1, a semiconductor device includes a substrate 1 constituted of a semiconductor of a hexagonal structure and having a substrate principal plane 101 which is a polar plane, and a semiconductor layer 2 constituted of a nitride-base compound semiconductor of a hexagonal structure disposed on the substrate principal plane 101 and having a principal plane 201 which is a polar plane, an m-side face 202 which is a (1-100) plane (m-plane) orthogonal to the principal plane, and an a-side face 203 which is a (11-20) plane (a-plane) orthogonal to the (1-100) plane, the faces 202 and 203 being arranged adjacently to the principal plane, and where an outer edge portion of a section along the (1-100) plane is mesa-shaped. FIG. 2 is a sectional view cut along the (1-100) plane of the semiconductor device illustrated in FIG. 1. The hexagonal crystal structure will be described below in detail including the m and a-planes.

The semiconductor layer 2 is formed on the substrate principal plane 101 of the substrate 1 by crystal growth. Thus, as in the case of the substrate 1, the principal plane 201 becomes a polar plane (c-plane). In the example illustrated in FIG. 2, the semiconductor layer 2 is formed by sequentially stacking a first conductive semiconductor layer 21 of the first conductivity type, an active layer 22, and a second conductive semiconductor layer 23 of the second conductivity type which are all nitride-base compound semiconductors on the substrate 1 in this order. First and second conductive carriers are respectively supplied from the first and second semiconductor layers 21 and 23 to the active layer 22.

In the outer edge portion of the principal plane 201 of the semiconductor layer 2, an area along the a-side face 203 which is the a-plane is mesa-etched to form a step portion 204, and an end of the a-side face 203 of the semiconductor layer 2 is formed into a mesa shape. In other words, the principal plane 201 includes two areas, i.e., first and second areas 2011 and 2012 sandwiching the step portion 204 and different from each other in distance from the substrate principal plane 101. As illustrated in FIG. 2, the first area 2011 is shorter in distance from the substrate principal plane 101 than the second area. Thus, an outer edge portion of a section along the m-side face 202 of the semiconductor layer 2 is formed into a mesa shape.

As described above, in the hexagonal crystal structure, a most easily cleaved plane (cleaved plane) is an m-plane ([1-100] plane) and, when marking-off is carried out perpendicularly to the m-plane, a crack is generated in the surface of the semiconductor device to extend from the cut portion to the m-plane. However, in the case of the semiconductor device illustrated in FIGS. 1 and 2, the principal plane 201 of the semiconductor layer 2 has a two-stage height sandwiching the step portion 204. This step portion 204 is formed by etching the principal plane 201 of the semiconductor layer 2 before chip manufacture as described below. Thus, even when a crack is generated to extend from the cut portion during the chip manufacture, the crack is stopped by the step portion 204 formed in the principal plane 201 to stay in the first area 2011 in the principal plane 201. In other words, the crack can be prevented from reaching an area where the active layer 22 or the second semiconductor layer 23 is formed to affect characteristics of the semiconductor device. As a result, a reduction in yield of the semiconductor device can be suppressed.

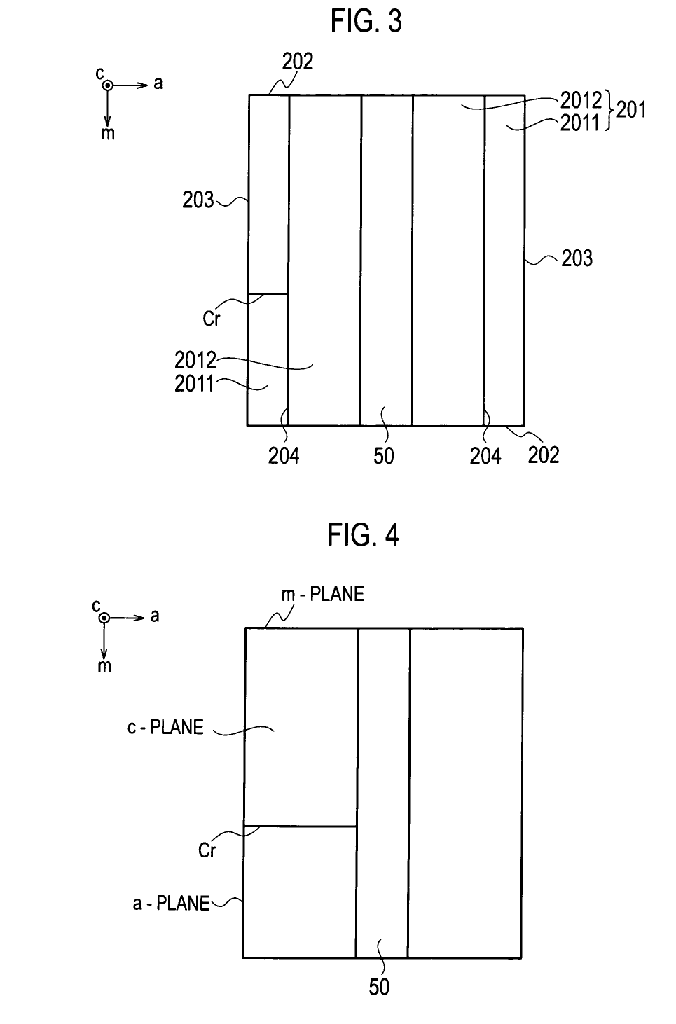

FIG. 3 is a top view illustrating the semiconductor device of the first embodiment of the present invention. As illustrated in FIG. 3, a crack Cr extending from the end of the semiconductor device stops at the step portion 204 formed in the principal plane 201. FIG. 4 illustrates an example where a semiconductor layer 2 includes no step portion 204. In a semiconductor device illustrated in FIG. 4, a crack Cr extends from an end of an a-plane side along an m-plane to a ridge stripe 50. Thus, characteristics of the semiconductor device illustrated in FIG. 4 are affected by the crack Cr.

An operation of the semiconductor device illustrated in FIGS. 1 and 2 will be described below. FIG. 2 illustrates an example where the first conductive type is an n type while the second conductive type is a p type. In other words, electrons are injected from the first semiconductor layer 21 into the active layer 22, while holes are injected from the second semiconductor layer 23 into the active layer 22. In the active layer 22, the electrons and the holes that have been injected are recoupled with each other to emit a light. In other words, the semiconductor device illustrated in FIGS. 1 and 2 functions as a semiconductor laser diode. Needless to say, however, the first conductive type may be a p type while the second conductive type may be an n type.

The active layer 22 has, for example, a multiple quantum well structure (MQW) containing an indium gallium nitride (InGaN), and amplifies the light emitted by recoupling the electrons and the holes with each other. The active layer 22 is formed by, for example, alternately stacking InGaN layers each having a film thickness 3 nm and GaN layers each having a film thickness 9 nm repeatedly by a plurality of cycles. In this case, the InGaN layer has a band gap made relatively small by setting a composition ratio of Indium (In) to 5% or more, and constitutes a quantum well layer. On the other hand, the GaN layer functions as a barrier layer of a relatively large band gap. The InGaN and GaN layers are alternately stacked repeatedly by 2 to 7 cycles to constitute an active layer 22 of a MQW structure. An emitted light wavelength can be set to, for example, 400 m to 500 nm, by adjusting the In composition ratio in the quantum well layer (InGaN layer).

The first semiconductor layer 21 is formed by, for example, stacking an n type clad layer 212 and an n type guide layer 213 in order from the substrate 1 side. The n type clad layer 212 is an n type aluminum gallium nitride (AlGaN) layer having a film thickness of 1.5 μm or less, for example, about 1 μm. The n type guide layer 213 is an n type GaN layer having a film thickness of about 0.1 μm.

In the first semiconductor layer 21, a part of an upper portion in a height direction is eliminated to form a step portion 204. More specifically, in the end of the a-side face 203, the n type guide layer 213 and parts of an upper portion of the n type clad layer 212 in the height direction are etched to be eliminated, thereby forming a cut section of the first semiconductor layer 21 along the m-plane into a convex shape. In other words, the first semiconductor layer 21 is thicker in a center than in the outer edge portion of the a-side face 203. As a result, the principal plane 201 of the semiconductor layer 2 is provided with first and second areas 2011 and 2012 sandwiching the step portion 204 and different from each other in distance from the substrate principal plane 101. The first area 2011 is an upper surface of the n type clad layer 212 exposed by etching, and the second area 2012 is an upper surface of the second semiconductor layer 23.

The second semiconductor layer 23 is formed by, for example, stacking a p type electron block layer 231, a p type guide layer 232, a p type clad layer 233, and a p type contact layer 234 on the active layer 22 in this order. The p type electron block layer 231 is a p type AlGaN layer having a film thickness of about 20 nm. The p type guide layer 232 is a p type GaN layer having a film thickness of about 0.1 μm. The p type clad layer 233 is a p type AlGaN layer having a film thickness of 1.5 μm or less, for example, 0.4 μm. The p type contact layer 234 is a p type GaN layer having a film thickness of 0.3 μm.

The semiconductor device of the first embodiment further includes n side electrode 41 and p side electrode 42. The n side electrode 41 is disposed in contact with a backside of the substrate 1 facing the substrate principal plane 101. The p side electrode 42 is disposed in contact with a plane facing a plane of the second semiconductor layer 23 which is brought into contact with the active layer 22. The n side electrode 41 is made of, for example, aluminum (Al). The p side electrode 42 is made of, for example, a palladium (Pd)-gold (Au) alloy.

The p type contact layer 234 is a low-resistance layer for reducing electric resistance between the second semiconductor layer 23 and the p side electrode 42. The p type contact layer 234 is formed by doping a GaN semiconductor with magnesium (Mg) as a p type dopant, for example, at a high concentration of 3×10¹⁹ cm³. When a part of the upper surface of the first semiconductor layer 21 is exposed to form an n side electrode, an n type contact layer may be formed as a low-resistance layer for reducing electric resistance between the first semiconductor layer 21 and the n side electrode. The n type contact layer is formed by, for example, doping a GaN semiconductor having a film thickness of about 2 μm with silicon (Si) as an n type dopant at a high concentration of about 3×10¹⁸ cm⁻³.

The n type clad layer 212 and p type clad layer 233 constituted of AlGaN layers are formed to provide a “light confinement effect” for confining a light generated in the active layer 22 of the MQW structure constituted of the InGaN and GaN layers between the n type clad layer 212 and p type clad layer 233. The n type clad layer 212 is formed by doping an AlGaN semiconductor with Si as an n type dopant, for example, at a doping concentration of 1×10¹⁸ cm⁻³. The p type clad layer 233 is formed by doping Mg as a p type dopant, for example, at a doping concentration of 1×10¹⁹ cm⁻³. The n type clad layer 212 is larger in band gap than the n type guide layer 213, and the p type clad layer 233 is larger in band gap than the p type guide layer 232. This way, good light confinement can be carried out.

The n type guide layer 213 and p type guide layer 232 are semiconductor layers formed to provide a “carrier confinement effect” for confining carriers (electrons and holes) in the active layer 22. Thus, efficiency of recoupling of electrons and holes in the active layer 22 is increased. The n type guide layer 213 is formed by doping a GaN semiconductor with Si as an n type dopant, for example, at a doping concentration of 1×10¹⁸ cm⁻³. The p type guide layer 232 is formed by doping a GaN semiconductor with Mg as a p type dopant, for example, at a doping concentration of 5×10¹⁸ cm³.

The p type block layer 231 is formed by doping an AlGaN semiconductor with Mg as a p type dopant, for example, at a doping concentration of 5×10¹⁸ cm⁻³. The p type block layer 231 prevents flowing-out of electrons from the active layer 22, thereby increasing recoupling efficiency of electrons and holes.

A part of the upper portion of the second semiconductor layer 23 is eliminated to form a ridge stripe 50. More specifically, parts of the p type contact layer 234, the p type clad layer 233, and the p type guide layer 232 are etched to be eliminated, thereby forming a ridge stripe 50 whose section cut along the m-plane is almost trapezoidal (mesa-shaped). The ridge stripe 50 extends in a direction of an m-axis. The n type guide layer 213, the active layer 22, and the p type guide layer 232 constitute Fabry-Perot resonator where end surfaces of both longitudinal ends of the ridge stripe 50 are resonator end surfaces. A light emitted in the active layer 22 reciprocates between the end planes of both longitudinal ends of the ridge stripe 50 to be amplified by induced emission. A part of the amplified light is output as a laser beam from the longitudinal end plane to the outside of the semiconductor device. Through formation of the ridge stripe 50, the upper surface of the p type guide layer 232 exposed by etching becomes a second area 2012 of the principal plane 201.

As illustrated in FIG. 2, an insulating film 30 is disposed to cover exposed portions of the p type guide layer 232 and clad layer 233 so that the p side electrode 42 can be brought into contact with only the p type contact layer 234 of a top surface (striped contact area) of the ridge stripe 50. This way, currents concentrate in the ridge stripe 50 to enable efficient laser oscillation. Portions other than the contact area with the p side area 42 are covered with the insulating film 30, thereby protecting a plane of the ridge stripe 50. Thus, control can be facilitated by moderating horizontal light confinement, and current leakage from the side face can be prevented. For the insulating film 30, a material having a refractive index larger than 1, for example, a silicon oxide (SiO₂) film or a zirconium dioxide (ZrO₂) film can be employed.

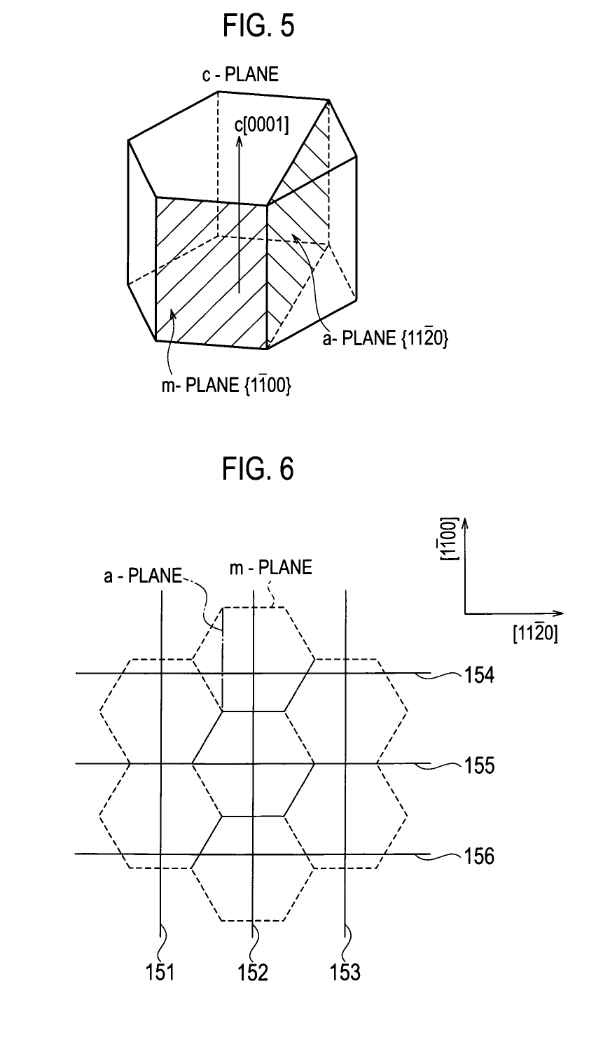

Next, a crystal structure of the semiconductor device illustrated in FIGS. 1 and 2 will be described. The GaN substrate has a hexagonal crystal structure. Thus, for example, when the substrate 1 is a GaN substrate where a substrate principal plane 101 is a c-plane, a semiconductor layer 2 made of a nitride-base compound semiconductor crystal-grown on the substrate principal plane 101 has a hexagonal crystal structure where a principal plane 201 is a c-plane. Referring to FIG. 5, the hexagonal crystal structure will be described. FIG. 5 schematically illustrates a unit cell of the hexagonal crystal structure.

A c-axis [0001] of a hexagonal system extends in an axial direction of a hexagonal column, and a plane (top surface of the hexagonal column) where the c-axis is a normal line is a c-plane [0001]. The c-plane exhibits characteristics different between + c-axis side and − c-axis side, and the c-plane is called a polar plane. In crystals of the hexagonal structure, a polarizing direction is along the c axis.

In the hexagonal system, six side faces of the hexagonal column are all m-planes ([1-100] planes), and a plane passing through a pair of ridgelines not adjacent to each other is an a-plane ([11-20] plane). The m-plane and a-plane are crystal planes perpendicular to the c-plane, and m-plane and a-plane having no polarities, in other words, nonpolar planes, as m-plane and a-plane are orthogonal to the polarizing direction.

FIG. 6 illustrates a part of the upper surface of the substrate 1 where a plurality of semiconductor device illustrated in FIGS. 1 and 2 is formed along with the hexagonal crystal structure. In other words, FIG. 6 illustrates the hexagonal crystal structure from the normal direction of the c-plane which is a top surface of the column, and each unit cell of the hexagonal crystal structure is indicated by a broken line. Stated differently, each m-plane of the unit cell is indicated by a broken line.

In FIG. 6, cut lines 151 to 156 indicating cut planes for dividing the substrate 1 into a plurality of chips are solid lines. A first cutting direction where the cut lines 151 to 153 extend and a second cutting direction where the cut lines 154 to 156 extend are orthogonal to each other. In other words, a principal plane shape of a chip obtained by dividing the substrate along the cut lines 151 to 156 is rectangular. Hereinafter, a chip having a rectangular principal plane shape will be referred to as a “rectangular chip”. A plane cutting the substrate 1 along the cut lines 151 to 153 corresponds to the a-side face 203 of the semiconductor device illustrated in FIG. 1. A plane cutting the substrate 1 along the cut lines 154 to 156 corresponds to the m-side face 202.

In the substrate 1 on which the semiconductor device is manufactured, an orientation reference such as an orientation flat is formed beforehand. Thus, the m-plane and the a-plane can be identified by using such an orientation reference. FIG. 6 illustrates only the six cut lines 151 to 156 for convenience. Needless to say, however, the number of cut lines is decided according to an area of the substrate 1 before division or an area of the rectangular chip after division.

In the example illustrated in FIG. 6, the cut lines 151 to 153 are set perpendicular to the m-plane. The m-plane perpendicular to the cut lines 151 to 153 is set as a “reference m-plane”. The cut lines 154 to 156 are set parallel to the reference m-plane, and perpendicular to the a-plane (“reference a-plane”) orthogonal to the reference m-plane indicated by a chain line in FIG. 6. In other words, the substrate 1 is divided along the cut lines 154 to 156 so that a pair of m-side faces 202 facing the semiconductor device as the rectangular chip illustrated in FIG. 1 can be perpendicular to the m-axis. An a-side face 203 of the rectangular chip adjacent to the m-side face 202 is divided along the cut lines 151 to 153 to be perpendicular to the a-axis.

A method for manufacturing the semiconductor device of the first embodiment of the present invention will be described below. The method for manufacturing the semiconductor device described below is only an example. Needless to say, other various methods including a modified example can be employed.

(1) A substrate 1 where a c-plane is a principal plane is prepared. The substrate 1 is, for example, a GaN substrate having a thickness of about 350 μm. A semiconductor layer 2 is grown on a substrate principal plane 101 of the substrate 1 by metalorganic chemical vapor deposition (MOCVD). Specifically, an n type first semiconductor layer 21, an active payer 22, and a p type second semiconductor layer 23 are sequentially stacked.

(2) A part of the second semiconductor layer 23 is eliminated to form a ridge stripe 50 by dry etching such as plasma-etching. Specifically, for example, after a photoresist film is deposited on a full surface of the second semiconductor layer 23, by a photolithography technology, the photoresist of a portion to be etched is eliminated to expose a part of a surface of the second semiconductor layer 23. Then, by using the photoresist film as a mask, a part of the second semiconductor layer 23 is etched to be eliminated, thereby forming a ridge stripe 50. The ridge stripe 50 is formed to be parallel to an m-axis direction.

(3) An insulating film 30 is formed on an upper surface of the semiconductor layer 2 by a lift-off method. Specifically, after a striped mask is formed by a photoresist film, an insulator thin film is formed to cover all of a p type guide layer 232, a p type clad layer 233, and a p type contact layer 234. This insulator thin film is lifted off to form an insulating film 30 so that only a top surface of the p type contact layer 234 can be exposed.

(4) A p side electrode 42 is formed on the insulating film 30 to come into contact with the exposed top surface of the p type contact layer 234. An n side electrode 41 is formed on a backside of the substrate 1.

(5) To obtain a desired chip shape, for example, cut lines 151 to 156 are set as illustrated in FIG. 6. In this case, the cut lines 151 to 153 are set perpendicular to a reference m-plane, while the cut lines 154 to 156 are set parallel to the reference m-plane. The reference m-plane can be set by using an orientation flat formed in the substrate 1. For example, an m-plane parallel to the orientation flat is set as a reference m-plane.

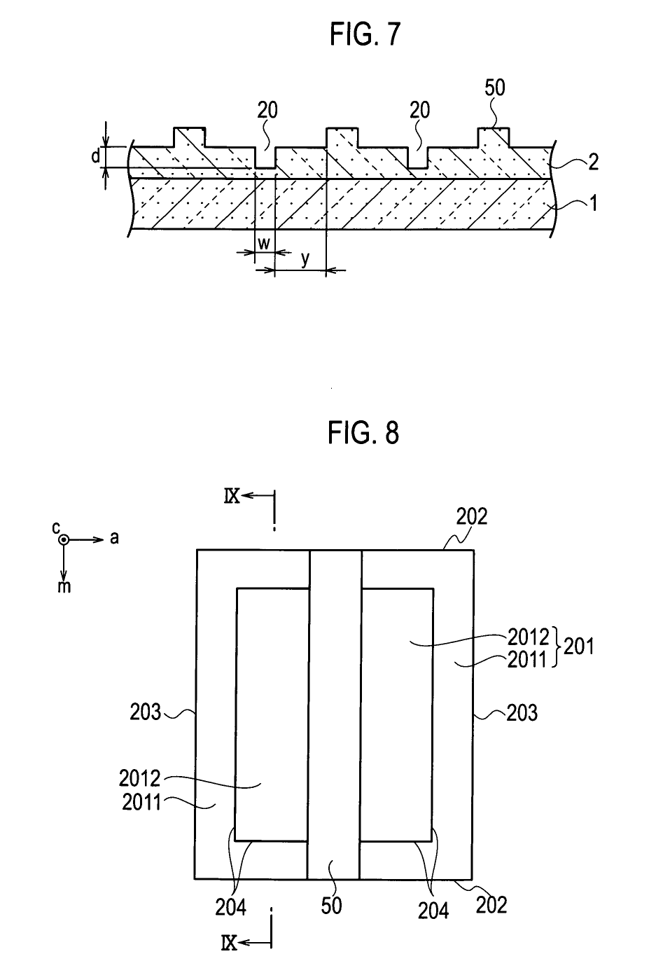

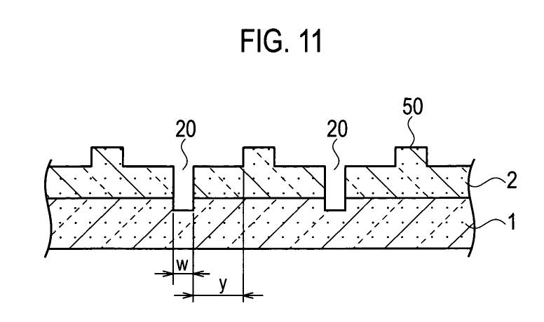

(6) As illustrated in FIG. 7, trenches 20 are formed in the principal plane 201 of the semiconductor layer 2 along the cut lines 151 to 153. Specifically, each trench 20 is formed from the principal plane 201 of the semiconductor layer 2 to a midpoint of a boundary plane (substrate principal plane 101) between the semiconductor layer 2 and the substrate 1 along the reference m-plane orthogonal to the principal plane 201. In this case, preferably, the trenches 20 are formed so that the cut lines 151 to 153 can be centers of the trenches 20. The trench 20 extends in the m-axis direction. A depth d of the trench 20 is, for example, about 0.5 to 1 μm. As illustrated in FIG. 2, the trench 20 may also be formed so as to reach the n type clad layer 212 beyond the active layer 22. The trench 20 is not limited to the above-described shape, and for example, the trench 20 may also be formed so as to reach an inside of the substrate 1 as illustrated in FIG. 11. Alternatively, the trench 20 may also be formed until the substrate principal plane 101 is just exposed. A width w of the trench 20 is, for example, about 30 μm. When the width w of the trench 20 is too small, the step portion formed by etching is less likely to function as a crack blocker. Thus, it is preferable that the width w be set at 20 μm or more. Furthermore, when a width y of the semiconductor layer 2 left without being etched is too small, a light emitting pattern of the laser is affected. Thus, it is preferable that the width y be set at 30 μm or more. The trench 20 may be formed by, for example, using the photoresist as a mask, and dry-etching the p side electrode 42, the insulating film 30, and a part of the upper portion of the semiconductor layer 2 in a height direction. When a ZrO₂ film is used for the insulating film 30, fluorine gas may be used for etching the insulating film 30. For etching the semiconductor layer 2, chlorine gas may be used.

(7) Marking-off is carried out along the cut lines 151 to 153 set in the trenches 20 and the cut lines 154 to 156 set parallel to the reference m-plane.

(8) The substrate 1 is cleaved along a marked-off place to be divided into a plurality of chips, thereby completing the semiconductor device illustrated in FIGS. 1 and 2. For example, a cleaving blade is brought into contact with the backside of the substrate 1 in a position corresponding to the marked-off place to be braked, thereby cleaving the substrate 1.

Through the aforementioned manufacturing method, the semiconductor device is manufactured, where four side faces as nonpolar planes orthogonal to the principal plane 201, in other words, the two opposing m-side faces 202 which are m-planes and the two opposing a-side faces 203 which are a planes are adjacent to the principal plane 201. Because of formation of the trench 20, the semiconductor device after division includes a step portion 204. Stated differently, an outer edge portion of a section of the semiconductor device manufactured by the aforementioned method along the m-plane is mesa-shaped. A width of a step portion of such a mesa shape becomes a half of the width w of the trench 20.

The example of dividing the substrate 1 through cleaving has been described. However, the substrate 1 may be divided by dicing. For example, when a width w of the trench 20 is about 30 μm, the substrate 1 can be divided into chips by using a dicing blade having a blade thickness of about 10 μm. Alternatively, a portion from a bottom of the trench 20 to a midway of the backside of the substrate 1 may be diced to form a new trench, and then the substrate 1 may be divided into chips by cleaving.

As described above, when marking-off is carried out in the m-axis direction, cracks easily occur in the surface of the semiconductor device along the m-plane which is a cleaved plane. However, according to the manufacturing method of the semiconductor device, when marking-off is carried out along the cut lines 151 to 153 in parallel to the m-axis, even if cracks occur in the axis direction from the cut lines 151 to 153, cracks generated in the bottom of the trench 20 stop at the side wall of the trench 20, in other words, at the step portion 204. As a result, an influence of cracks on characteristics of the semiconductor device can be prevented.

The manufacturing method has been described by way of example of forming the n side electrode 41 before the cut lines 151 to 156 are set. However, the n side electrode 41 may be formed after the cut lines 151 to 156 are set. In this case, n side electrodes 41 can be formed in areas excluding those of the cut lines 151 to 156. In other words, nonformation of an n side electrode 41 in a portion divided by cleaving or dicing facilitates chip manufacture.

In view of abrasion of the dicing blade, preferably, the substrate 1 is wrapped to polish its backside thin before dicing. In terms of abrasion of the dicing blade, the smaller a thickness of the substrate 1, the better. In view of handling the wrapping, polishing up to about 100 μm is enough.

As described above, according to the method for manufacturing the semiconductor device of the first embodiment of the present invention, since the trench 20 is formed to extend perpendicularly to the cleaved plane, even when marking-off perpendicular to the cleaved plane generates cracks in parallel to the cleaved plane, the generated cracks stop at the side wall of the trench 20. As a result, a method for manufacturing a semiconductor device can be provided, which can divide a substrate 1 into chips while preventing an influence of the generated cracks on characteristics of the semiconductor device, and suppressing a reduction in yield.

### Second Embodiment

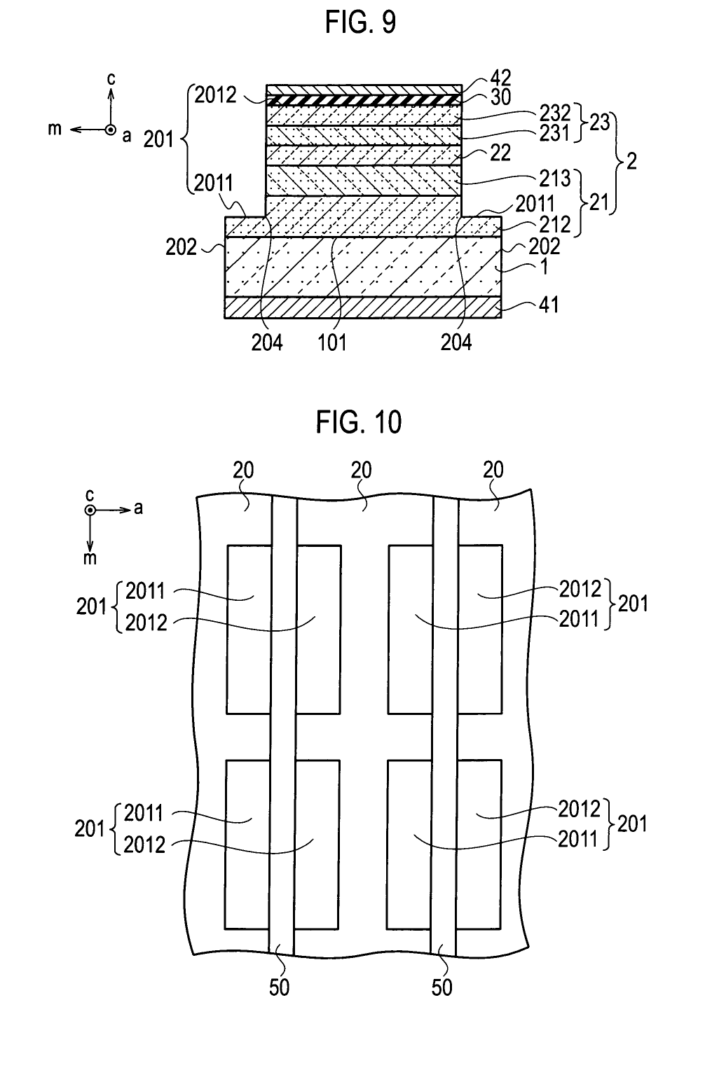

As illustrated in a top view of FIG. 8, and a sectional view of FIG. 9 cut along the line IX-IX of FIG. 8, a semiconductor device of a second embodiment of the present invention is different from the semiconductor device illustrated in FIGS. 1 and 2 in that an outer edge portion of a section along an a-side face 203 as an a-plane orthogonal to a principal plane 201 of a semiconductor layer 2 is mesa-shaped except for an area where a ridge stripe 50 is formed. In other words, in the outer edge portion of the principal plane 201 of the semiconductor layer 2, an area except for the area of the ridge stripe 50 is mesa-etched to form a step portion 204. Other components are similar to those of the first embodiment illustrated in FIGS. 1 and 2.

In the case of the semiconductor device illustrated in FIGS. 1 and 2, in the outer edge portion of the principal plane 201 of the semiconductor layer 2, the area along the a-side face which is an a plane is mesa-etched to form the step portion 204, and the end of the a-side face 203 of the semiconductor layer 2 is mesa-shaped. On the other hand, in the case of the semiconductor device illustrated in FIGS. 8 and 9, in the outer edge portion of the principal plane 201 of the semiconductor layer 2, not only the area along the a-side face 203 but also an area along an m-side face 202 which is an m-plane orthogonal to the principal plane 201 are mesa-etched to form step portions 204. Thus, not only an end of the a-side face 203 of the semiconductor layer 2 but also an end of the m-side face 202 are mesa-shaped.

In the semiconductor device illustrated in FIGS. 8 and 9, as in the case of the first embodiment, when cracks are generated to extend from cut portions during chip manufacture, the cracks stop at the step portion 204 formed in the principal plane 201 to stay in a first area 2011 of the principal plane 201. As a result, an influence of cracks on characteristics of the semiconductor device is prevented, and a reduction in yield of the semiconductor device is suppressed. Others are substantially similar to those of the first embodiment, and description thereof will be omitted to avoid repetition.

A method for manufacturing the semiconductor device of the second embodiment of the present invention will be described below. The manufacturing method of the semiconductor device described below is only an example and, needless to say, various other methods including a modified example can be employed.

(1) As in the case of the manufacturing method of the first embodiment described above, by MOCVD, a semiconductor layer 2 is crystal-grown on a substrate 1 where a c-plane is a principal plane. Then, a ridge stripe 50 is formed. After formation of an insulating film 30, p side electrode 42 and n side electrode 41 are formed.

(2) To obtain a desired chip shape, for example, cut lines 151 to 156 are set as illustrated in FIG. 6. The cut lines 151 to 153 are set perpendicular to a reference m-plane, while the cut lines 154 to 156 are set parallel to the reference m-plane.

(3) Along the set cut lines 151 to 156, trenches 20 are formed in the principal plane 201 of the semiconductor layer 2 except for an area where the ridge stripe 50 has been formed. Specifically, from the principal plane 201 of the semiconductor layer 2 to a midpoint of a boundary plane (substrate principal plane 101) between the semiconductor layer 2 and the substrate 1, trenches 20 are formed in parallel to m-plane and a-plane orthogonal to the principal plane 201. Preferably, the trenches 20 are formed so that the cut lines 151 to 156 can be centers of the trenches 20. As illustrated in FIG. 10, the trenches 20 extend in directions of m and a-axes. FIG. 10 is a top view of the substrate 1 where the trenches 20 have been formed.

(4) Marking-off is carried out in the trenches 20 along the set cut lines 151 to 156.

(5) The substrate 1 is cleaved along the marked-off place to be divided into a plurality of chips, thereby completing the semiconductor device illustrated in FIGS. 8 and 9.

To carry out marking-off by emitting a laser beam, the insulating film 30 of the cut place may be eliminated beforehand. In other words, to cut an area where no trench 20 is formed, in addition to the step of forming trenches 20, the insulating film 30 of this area has to be eliminated by dry etching. However, according to the manufacturing method of the semiconductor device of the second embodiment of the present invention, the trenches 20 are simultaneously formed along all the cut lines 151 to 156. Thus, the step of eliminating the insulating film 30 for marking-off can be omitted, thereby enabling efficient manufacture of the semiconductor device.

### Other Embodiments

The first and second embodiments have been described by taking the example of the laser diode which includes the ridge stripe 50. However, a laser diode having no ridge stripe may be employed. A light emitting diode (LED) where an n type semiconductor layer, an active layer, and a p type semiconductor layer are stacked may be employed. Alternatively, the semiconductor layer 2 may employ other structures such as p-n junction for directly coupling together the n and p type semiconductor layers.

Various modifications will become possible for those skilled in the art after receiving the teachings of the present disclosure without departing from the scope thereof.

What is claimed is:

1. A method for manufacturing a semiconductor device, in which a wafer is divided into a plurality of semiconductor device, the wafer including a semiconductor layer made of a nitride-base compound semiconductor of a hexagonal structure and stacked on a substrate where a polar plane is a principal plane, comprising:
setting cut line in parallel to a normal direction of a (1-100) plane orthogonal to the principal plane and in parallel to a normal direction of a (11-20) plane orthogonal to the (1-100) plane;
forming, along the cut line parallel to the normal direction of the (1-100) plane, a trench from the principal plane of the semiconductor layer to a midpoint of the principal plane and a boundary plane which is between the semiconductor layer and the substrate; and
cutting the wafer along the cut lines to divide the wafer into the plurality of semiconductor device where four side faces which are nonpolar planes orthogonal to the principal plane are set adjacent to the principal plane.

2. The method of claim 1, further comprising forming, along the cut line parallel to the normal direction of the (11-20) plane, a trench from the principal plane of the semiconductor layer to the midpoint of the principal plane and the boundary plane which is between the semiconductor layer and the substrate.

3. The method of claim 1, wherein the trench is formed by dry etching.

4. The method of claim 1, wherein the wafer is cleaved along the cut lines.

5. The method of claim 1, wherein the wafer is scribed along the cut lines.

6. The method of claim 1, wherein the wafer is scribed along the cut lines to form a new trench, and the wafer is cleaved along the new trench.

7. The method of claim 1, further comprising eliminating a part of an upper portion of the semiconductor layer to form a ridge stripe which extends in the normal direction of the (1-100) plane.

8. A semiconductor device comprising:
a substrate made of a semiconductor of a hexagonal structure and including a substrate principal plane which is a polar plane; and
a semiconductor layer made of a nitride-base compound semiconductor of a hexagonal structure and disposed on the substrate principal plane, and including a principal plane as a polar plane, an m-side face as a (1-100) plane orthogonal to the principal plane, and an a-side face as a (11-20) plane orthogonal to the (1-100) plane disposed adjacently to the principal plane, an outer edge portion of a section along the (1-100) plane being mesa-shaped.

9. The semiconductor device of claim 8, wherein the semiconductor layer includes a first conductive semiconductor layer of a first conductivity type and a second conductive semiconductor layer of a second conductivity type, and a section of the second semiconductor layer along the (1-100) plane is convex-shaped.

10. The semiconductor device of claim 8, wherein a section of the outer edge portion of the semiconductor layer along the (11-20) plane is mesa-shaped.

11. The semiconductor device of claim 8, wherein the semiconductor layer has a structure formed by stacking a first conductive semiconductor layer of a first conductivity type, an active layer, and a second conductive semiconductor layer of a second conductivity type in this order.

12. The semiconductor device of claim 11, wherein the active layer has a multiple quantum well structure containing an indium gallium nitride.

13. The semiconductor device of claim 11, further comprising a ridge stripe formed by eliminating a part of an upper portion of the second semiconductor layer to extend in a normal direction of the (1-100) plane.

14. The semiconductor device of claim 8, wherein the substrate is a gallium nitride substrate.

15. A semiconductor laser in which a nitride semiconductor layer is stacked on a gallium nitride substrate, comprising:
a ridge stripe formed by etching the nitride semiconductor layer; and
a step portion formed by etching the nitride semiconductor layer, the step portion being provided parallel to the ridge strip on a side face of the semiconductor laser, wherein the side surface is adjacent to a principal plane of the gallium nitride substrate and to a resonance plane of the semiconductor laser.

16. The semiconductor laser of claim 15, further comprising an additional step portion formed by etching the nitride semiconductor layer on the resonance plane of the semiconductor layer so as to leave at least the ridge stripe.

17. The semiconductor laser of claim 15, wherein the step portion is formed by etching the nitride semiconductor layer beyond an active layer of the nitride semiconductor layer into a vicinity of the gallium nitride substrate or into an inside of the gallium nitride.

18. The semiconductor laser of claim 15, wherein a width of the step portion is 10 μm or more.

19. The semiconductor laser of claim 15, wherein a width of the nitride semiconductor layer between the step portion and the ridge stripe is 30 μm or more.
